(19) United States
(12) Patent Application Publication
(10) Pub. No.: US 2002/0039622 A1
(43) Pub. Date: Apr. 4, 2002

(54) Method of depositing a metallic film on a substrate

(76) Inventors: Rajendra Solanki, Portland, OR (US); Balu Pathangey, Phoenix, AZ (US)

Correspondence Address: Richard T. Redano, Duane, Morris & Heckscher LLP, One Greenway Plaza, Suite 500, Houston, TX, 77046, US

(21) Appl. No.: 09/968,370

(22) Filed: Oct. 1, 2001

Related U.S. Application Data
(60) Provisional application No. 60/237,043, filed on Oct. 2, 2000.

(51) Int. Cl. C23C 16/00

(52) U.S. Cl. 427/250

(57) ABSTRACT

The present invention relates to a method of depositing a metallic film on a substrate. This method uses a carrier gas to deposit a source metal in the presence of an aqueous reducing agent such that the rate of deposition can be controlled by controlling the flow rate of the carrier gas.

This application claims priority from provisional application serial No. 60/237,043, filed on Oct. 2, 2000.

### BACKGROUND OF THE INVENTION

1. Field of Invention

The present invention relates to a method of depositing a metallic film on a substrate. This method uses a carrier gas to deposit a source metal in the presence of an aqueous reducing agent such that the rate of deposition can be controlled by controlling the flow rate of the carrier gas.

2. Description of The Prior Art

Chemical vapor deposition techniques have been used to deposit metallic substances on substrates. With the advent of nanotechnology, there is an increasing need to develop methods for depositing nanoscale metallic films on substrates for use in producing items such as circuit boards and architectural coatings.

### SUMMARY OF INVENTION

An invention is described for conformally depositing nanoscale metallic films, such as copper, silver, gold, cobalt, or nickel using the process of flow modulated chemical vapor deposition. Deposition of copper film is currently of significant interest for making interconnects in microelectronic devices because of its low resistivity that results in higher speed and its high resistance to electromigration that enhances its reliability. Other applications of copper include circuit board fabrication, catalyst preparation, and architectural coatings.

This invention uses a reaction between a reducing agent and a copper compound to produce a high purity, low resistance copper film over a wide range of substrates. The copper source can be hydrated (hexafluoroacetylacetonate) copper II (Cu(hfac)₂.XH₂0) or other copper β-diketonates. These copper compounds can be reduced into metallic copper using a second chemical component that is referred to as a reducing agent. Several reducing agents were investigated of which ethanol, isopropanol, and formaldehyde based solution produced bright and shiny copper colored films. The formaldehyde based solution (combination of specific percentages of formaldehyde, water and alcohol) produced the best films with resistivites (˜1.72 μΩ-cm) close to bulk values (1.67 μΩ-cm) which is of extreme importance for the advanced ULSI fabrication.

A simple experimental set-up was utilized where the reducing agent and the copper source were introduced into the reaction cell that contained the substrate. The substrate was placed on a heated platform that could be heated up to 450° C. Most of the depositions were produced at 300° C., although copper films were also produced at 210° C., however the deposition rate was slower than at higher temperatures.

The sources were transported with hydrogen (H₂) as the carrier gas that was bubbled through the reducing agent. To transport CU(hfac)₂, H₂ was first bubbled through water and then over the Cu compound heated to about 150° C.

The substrates include glass plates and silicon wafers that were coated with (blank patterned) TaN, TiN, and Ta. Best film adhesion was achieved over TaN and Tin at about 300° C. However, at about 350° C., adhesion was excellent on all these substrates. Similar method can be adopted for other technologically important metallic thin films.

This technique was also utilized to deposit several other metallic films. High purity silver films were deposit on glass and Si coated with TaN, TiN, and Ta (patterned and blank) where Ag source was trimethylphosphine (hexafluoroacetylacetonate) Ag(I). The reducing agents were again alcohol and formaldehyde based solution, as described above. The resistivity of films were about 1.7 μΩ- cm. Other metallic films that were similarly deposited include gold using Me₂Au(hfac) and Me₂Au(tfac), Pt from hexafluoroacetylacetonate Pt (II), and Co from hexfluoroacetylacetonate Co (III). The reducing agents were same mentioned above.

The present invention is directed toward a flow modulated CVD method for deposition of a wide range of high purity metallic films using an appropriate metal precursor and a reducing agent.

### DESCRIPTION OF THE DRAWINGS

FIG. 1 is a side view of an apparatus suitable for practicing the method of the present invention.

FIG. 2 is a block diagram of an embodiment of the present invention.

### DESCRIPTION OF THE PREFERRED EMBODIMENTS

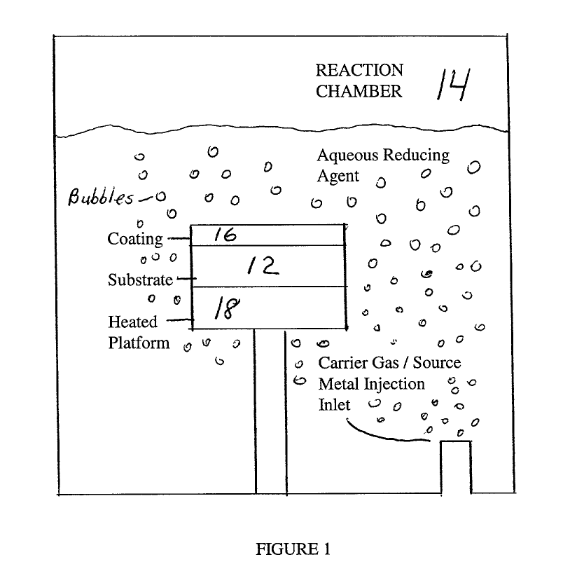

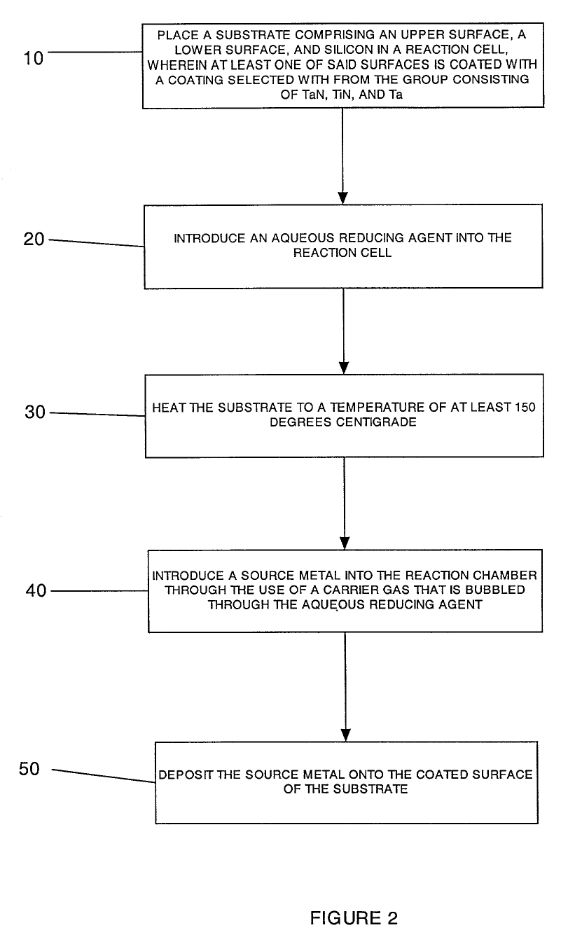

The present invention is directed toward a method of depositing a metallic film on a substrate. This invention comprises placing a substrate 12 comprising an upper surface, a lower surface, and silicon in a reaction cell or chamber 14, wherein at least one of said surfaces is coated with a coating 16 selected from the group consisting of TaN, TiN, and Ta, as shown in FIG. 1 and in block 10 of FIG. 2. In a preferred embodiment, the coating on the substrate is patterned.

In one preferred embodiment, the substrate is a silicon wafer. In another preferred embodiment, the substrate is a glass plate. In another preferred embodiment, the substrate is placed on a heated platform 18, as shown in FIG. 1. The invention further comprises heating the substrate to a temperature of at least 150° C., as shown in block 30 of FIG. 2.

The invention further comprises introducing a source metal into the reaction chamber through the use of the carrier gas that is bubbled through the aqueous reducing agent, as shown in FIG. 1 and in block 40 of FIG. 2. In one preferred embodiment, the substrate is heated to a temperature of at least 210° C. prior to introducing the source metal. In another preferred embodiment, the substrate is heated to a temperature of at least 300° C. prior to introducing the source metal.

In a preferred embodiment, the carrier gas is hydrogen. In a preferred embodiments, the reducing agent is selected from the group consisting of ethanol, isopropanol, and formaldehyde.

In a preferred embodiment, the source metal is hydrated copper II, or other copper β-diketonates. In another preferred embodiment, the source metal comprises silver. In this preferred embodiment, the source metal may be Ag(I). In another preferred embodiment, the source metal comprises a metal selected from the group consisting of Me, Pt, and Co.

The invention further comprises depositing the source metal onto the coated surface of the substrate, as shown in block 50 of FIG. 2. In a preferred embodiment, the deposition rate of source metal onto the substrate is controlled by controlling the rate at which the source metal is introduced into the reaction chamber.

The foregoing disclosure and description of the invention are illustrative and explanatory. Various changes in the size, shape, and materials, as well as in the details of the illustrative construction may be made without departing from the spirit of the invention.

What is claimed is:

1. A method of depositing a metallic film on a substrate comprising:
a. placing a substrate comprising an upper surface, a lower surface, and silicon in a reaction cell, wherein at least one of said surfaces is coated with a coating selected with from the group consisting of TaN, TiN, and Ta;
b. introducing an aqueous reducing agent into the reaction cell;
c. heating the substrate to a temperature of at least 150 degrees Centigrade;
d. introducing a source metal into the reaction chamber through the use of a carrier gas that is bubbled through the aqueous reducing agent; and
e. depositing the source metal onto the coated surface of the substrate.

2. The method of claim 1, wherein the reducing agent is selected from the group consisting of ethanol, isopropanol, and formaldehyde.

3. The method of claim 1, wherein the source metal is hydrated copper II.

4. The method of claim 1, wherein the source metal is a copper β-diketonates.

5. The method of claim 1, wherein the source metal comprises silver.

6. The method of claim 5, wherein the source metal is Ag(I).

7. The method of claim 1, wherein the source metal comprises a metal selected from the group consisting of Me, Pt, and Co.

8. The method of claim 1, wherein the substrate is heated to a temperature of at least 210 degrees Centigrade prior to introducing the source metal.

9. The method of claim 1, wherein the substrate is heated to a temperature of at least 300 degrees Centigrade prior to introducing the source metal.

10. The method of claim 1, wherein the substrate is placed on a heated platform.

11. The method of claim 1, wherein the carrier gas is hydrogen.

12. The method of claim 1, wherein the deposition rate of source metal onto the substrate is controlled by controlling the rate at which the source metal is introduced into the reaction chamber.

13. A method of depositing a metallic film on a substrate comprising:
a. placing a silicon wafer substrate comprising at least one outer surface, in a reaction cell, wherein the surface is coated with a coating is selected with from the group consisting of TaN, TiN, and Ta;
b. introducing an aqueous reducing agent into the reaction cell;
c. heating the substrate to a temperature of at least 150 degrees Centigrade;
d. introducing a source metal into the reaction chamber through the use of a carrier gas that is bubbled through the aqueous reducing agent; and
e. depositing the source metal onto the coated surface of the substrate.

14. The method of claim 13, wherein:
a. the source metal comprises cooper; and
b. the substrate is heated to a temperature of at least 210 degrees Centigrade prior to introducing the source metal.

15. The method of claim 13, wherein:
a. the source metal comprises silver; and
b. the reducing agent is selected from the group consisting of ethanol, isopropanol, and formaldehyde.

16. The method of claim 13, wherein the coating on said substrate is patterned.

17. A method of depositing a metallic film on a substrate comprising:
a. placing a substrate comprising an upper surface, a lower surface, and silicon on a heating platform in a reaction cell, wherein at least one of said surfaces is coated with a coating selected with from the group consisting of TaN, TiN, and Ta;
b. introducing an aqueous reducing agent into the reaction cell;
c. heating the substrate to a temperature of at least 150 degrees Centigrade;
d. introducing a source metal into the reaction chamber through the use of a carrier gas that is bubbled through the aqueous reducing agent; and
e. depositing the source metal onto the coated surface of the substrate.

18. The method of claim 17, wherein the substrate is a glass plate.

19. The method of claim 17, wherein the carrier gas is hydrogen.

20. The method of claim 17, wherein the substrate is heated to a temperature of at least 300 degrees Centigrade prior to introducing the source metal.
